(19) United States
(12) Patent Application Publication
(10) Pub. No.: US 2004/0056248 A1
(43) Pub. Date: Mar. 25, 2004

(54) Test key for detecting electrical isolation between a word line and a deep trench capacitor in dram cells

(76) Inventors: Chih-Cheng Liu, Taipei Hsien (TW); Wei-Wu Liao, Taipei Hsien (TW); Chuan Fu Wang, Taipei Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/065,187

(22) Filed: Sep. 25, 2002

(51) Int. Cl. H01L 23/58

(52) U.S. Cl. 257/48

(57) ABSTRACT

A test key includes a substrate, a deep trench capacitor formed in the substrate, and at least one active region defined on the substrate. The active region comprises a first region, a second region and an ion well. A thermal oxide layer is formed in the first region. A top-thin oxide layer is formed in the second region. The second region overlaps with the deep trench capacitor. At least one word line partially overlapping with the top-thin oxide layer. The ion well is electrically connected with a polysilicon electrode of the deep trench capacitor. The thermal oxide layer within the first region does not overlap with any word line.

### BACKGROUND OF INVENTION

1. Field of the Invention

The present invention relates to testcircuits, and more particularly, to a structure of a test key for detecting electrical isolation between a deep trench capacitor and a word line in DRAM cells.

2. Description of the Prior Art

In general, a memory cell of a dynamic random access memory (DRAM) is composed of a metal oxide semiconductor (MOS) switching transistor and a capacitor for storing data. With the coming of a generation of Ultra Large Scale Integrated (ULSI) Circuits, the sizes of memory cells have gotten smaller and smaller in order to increase the integration of DRAM devices. Thus, a DRAM cell with a deep trench capacitor (hereinafter referred to as “DT-DRAM”) is developed.

When fabricating DT-DRAM chips, forming a deep trench capacitor covered by a uniform top-thin oxide layer is one of the most important modules. Typically, a series of process control monitor (PCM) steps are carried out to inspect qualities of a deep trench capacitor. Among those PCM steps, electrical isolation between a deep trench capacitor and a word line is utilized to determine whether a deep trench is filled well and to identify qualities of the chemical mechanical process (CMP). It is known that dishing effects during a conventional CMP process might cause unqualified top-thin oxide layer over the deep trench capacitors, thereby resulting in leakage currents and associated reliability problems.

Please refer to FIG. 1 to FIG. 2. FIG. 1 is a schematic diagram of a prior art test key layout for detecting electrical isolation between a deep trench capacitor and a word line in DRAM cells. FIG. 2 is a cross-sectional view along line 1-1″ of the test key 10 shown in FIG. 9 . As shown in FIG. 1 and FIG. 2, a test key 10 comprises a plurality of deep trench capacitors 12a and 12b formed in a substrate 11, a plurality of active regions 14, and a plurality of word lines 16a and 16b laid over the substrate 11. Outside the active regions 14 is a shallow trench isolation (STI) region formed by conventional STI processes. Each of the active regions 14 is substantially divided into a first region 14a and a second region 14b (the area indicated by slant lines). The first region 14a includes a thermal gate oxide layer 15 formed over the substrate 11, and the second region 14b includes a top-thin oxide layer 22a filled in a recess of the substrate 11. The formation of the gate oxide layer 15 is known in the art. For example, a high-quality gate oxide layer 15 may be formed by using thermal oxidation process. The top-thin oxide layer 22a is formed by using chemical vapor. deposition (CVD) process. As seen in FIG. 2, each of the active regions 14 further comprises an ion well 14c implanted abutting upon the deep trench capacitor in the substrate 11. A contact 18 is provided for each of the active regions 14 and is electrically connected with the ion well 14c. The contact 18 is electrically connected with a bit line (not shown in figures) for supplying the ion well 14c with a pre-selected voltage.

The structure of a deep trench capacitor of DRAM cells is known in the art. For the sake of simplicity, the detailed structure of the deep trench capacitor is not shown in the figures. The deep trench capacitor 12a comprises a doped polisilicon layer 26a. Dopants of the doped polisilicon layer 26a diffuse into the adjacent substrate 11 to form a doped region 28a. The doped polisilicon layer 26a and the doped region 28a form a buried strap, which electrically connects a MOS transistor and deep trench capacitor of a DRAM cell. In a test key, the buried strap electrically connects the ion well 14c and a polysilicon electrode 26 of the deep trench capacitor 12a. Furthermore, a shallow trench isolation 24 isolates the deep trench capacitor 12a from the deep trench capacitor 12b. The top-thin oxide layer 22a and the shallow trench isolation 24 are simultaneously formed in a single CVD process. Typically, the top-thin oxide layer 22a and the shallow trench isolation 24 are composed of silicon dioxide. As best seen in FIG. 2, the thickness of the top-thin oxide layer 22a is less than the thickness of the shallow trench isolation 24, while greater than the thickness of the gate oxide layer 15.

It depends on the top-thin oxide layer 22a whether electrical isolation between the word lines 16a and 16b and the deep trench capacitors 12a and 12b is good or not. In general, in the semiconductor industry a breakdown voltage measurement is used to identify isolation of the top-thin oxide layer 22a. While measuring the breakdown voltage of the top-thin oxide layer 22a, voltages are applied on the word lines 16a and 16b atop the deep trench capacitors 12a and 12b and the ion well 14c beside the deep trench capacitors 12a and 12b.

However, due to limits of process technology or due to other factors, in the test key 10 of the prior art, the word lines are usually formed in an undesirable misalignment manner that some word lines overlaps with the underlying gate oxide layer 15 formed in a second region 14b of the active region 14. As shown in FIG. 3, the word line 16a covers portions of the gate oxide layer 15. Because a thickness of the gate oxide layer 15 is smaller than the top-thin oxide layer 22a, the breakdown voltage of the gate oxide layer 15, rather than the breakdown voltage of the top-thin oxide layer 22a, is measured by the previously mentioned method. That is, electrical isolation between the word line and the deep trench capacitor cannot be accurately detected from the test key 10 of the prior art.

### SUMMARY OF INVENTION

It is therefore a primary objective of the claimed invention to provide an improved structure of a test key so as to solve the above-mentioned problem.

According to the claimed invention, a test key includes a substrate, a deep trench capacitor formed in the substrate, and at least one active region defined on the substrate. The active region comprises a first region, a second region and an ion well. A thermal oxide layer is formed in the first region. A top-thin oxide layer is formed in the second region. The second region overlaps with the deep trench capacitor. At least one word line partially overlapping with the top-thin oxide layer. The ion well is electrically connected with a polysilicon electrode of the deep trench capacitor. The thermal oxide layer within the first region does not overlap with any word line.

To achieve the goal of this invention, in one aspect of this invention, a test circuit includes a substrate, a first deep trench polysilicon layer formed in the substrate, a first top-thin oxide layer disposed over the first deep trench polysilicon layer, a second deep trench polysilicon layer laterally formed in the substrate on one side of the first deep trench polysilicon layer, a second top-thin oxide layer disposed over the second deep trench polysilicon layer. A shallow trench isolation is embedded in the substrate and located between the first deep trench polysilicon layer and the second deep trench polysilicon layer. A word line is laid on the substrate. The word line partially covers the first top-thin oxide layer, the shallow trench isolation, and the second top-thin oxide layer. An ion well implanted in the substrate and is electrically connected with the first deep trench polysilicon layer. A contact electrically connects the ion well and a bit line for supplying the first deep trench polysilicon layer with a pre-selected voltage.

To achieve the goal of this invention, in another aspect of this invention, a test key for evaluating isolation quality of a top-thin oxide layer of deep trench DRAM cells includes a substrate, a first deep trench capacitor formed in the substrate, a first top-thin oxide layer disposed over the first deep trench capacitor, a second deep trench capacitor formed in the substrate and being electrically connected with the first deep trench capacitor, a second top-thin oxide layer disposed over the second deep trench capacitor. A shallow trench isolation is embedded in the substrate for isolating the first deep trench capacitor from the second deep trench capacitor. A first word line is formed on the substrate partially covering the first top-thin oxide layer, the shallow trench isolation, and the second top-thin oxide layer. An ion well is implanted in the substrate and being electrically connected with the first deep trench capacitor. A contact electrically connects the ion well and a bit line for supplying the first deep trench capacitor with a pre-selected voltage. The second deep trench capacitor is electrically connected with the first deep trench capacitor through a connecting region.

It is an advantage over the prior art that there is only one word line partially passing over two adjacent deep trench capacitors in the test key of the claimed invention. Thus, a width of the word line can be adjusted to prevent the word line from being located on the gate oxide layers under which an ion well is biased by a pre-selected voltage. As a result, electrical isolation between the word line and the deep trench capacitor can be accurately detected from the test key.

These and other objectives of the claimed invention will no doubt become obvious to those of ordinary skill in the art after reading the following detailed description of the preferred embodiment, which is illustrated in the multiple figures and drawings.

### BRIEF DESCRIPTION OF DRAWINGS

FIG. 1 is a schematic diagram of a prior art test key for detecting electrical isolation between a deep trench capacitor and a word line in DRAM cells.

FIG. 2 and FIG. 3 are cross-sectional views along line 1-1″ of the test key shown in FIG. 1.

FIG. 4 is a schematic diagram of a test key according to the first embodiment of present invention.

FIG. 5 is a cross-sectional view along line 4-4″ of the test key shown in FIG.4.

FIG. 6 is a schematic diagram of a test key according to the second embodiment of the present invention.

FIG. 7 is a cross-sectional view along line 6-6″ of the test key shown in FIG.6.

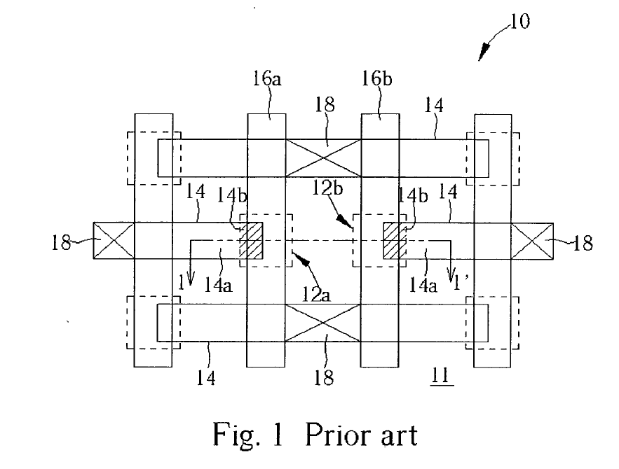

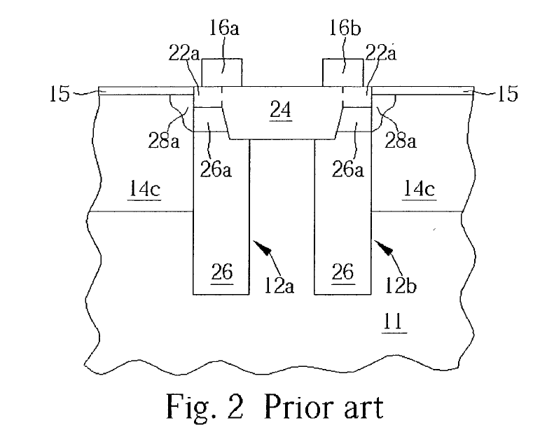

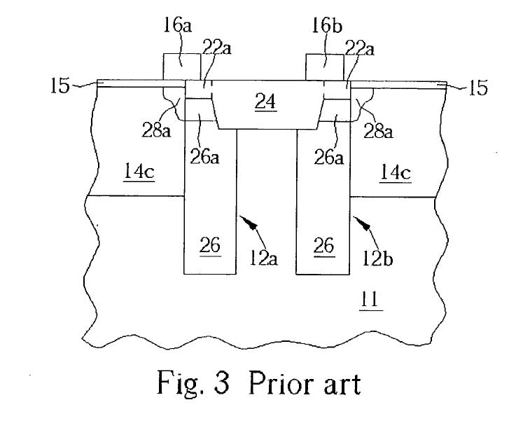

### DETAILED DESCRIPTION

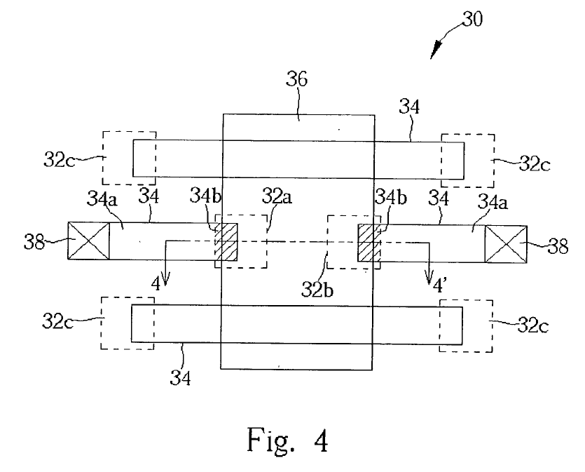

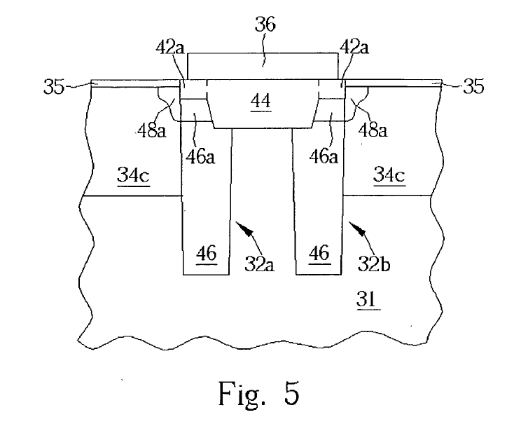

Please refer to FIG. 4 and FIG. 5. FIG. 4 is a schematic diagram of a test key according to the first preferred embodiment of the present invention. FIG. 5 is a cross-sectional view along line 4-4″ of the test key 30 shown in FIG. 4. As shown in FIG. 4, a test key 30 comprises a first deep trench capacitor 32a, a second deep trench capacitor 32b, a plurality of dummy deep trench capacitors 32c, a plurality of active regions 34, and a word line 36 partially passing over first deep trench capacitor 32a and the second deep trench capacitor 32b. Likewise, outside the active regions 14 is defined as a STI region formed by conventional STI processes. The active regions 34 can be further divided into a first region 34a and a second region 34b. The second region 34b is defined as the overlapping area between the active region 34 and the deep trench capacitors 32a and 32b as indicated by slant lines. The first region 34a includes a thermal gate oxide layer 35 formed over the substrate 31, and the second region 34b includes a top-thin oxide layer 42a filled in a recess of the substrate 31. The formation of the gate oxide layer 35 is known in the art. For example, a high-quality gate oxide layer 35 may be formed by using thermal oxidation process. The top-thin oxide layer 42a is formed by using chemical vapor deposition (CVD) process. As seen in FIG. 5, each of the active regions 34 further comprises an ion well 34c implanted in an area abutting upon the deep trench capacitor in the substrate 31. A contact 38 is provided and is electrically connected with the ion well 34c. The contact 18 is electrically connected with a bit line (not shown in figures) for supplying the ion well 34c with a pre-selected voltage. It should be noted that not every active region 34 of the test key 30 is provided with a contact 18. With reference to FIG. 4, the active region 34 that connects two dummy deep trench capacitors 32c his not provided with a contact 18. Furthermore, the dummy deep trench capacitors 32c does not overlap with any word line. In addition, as best seen in FIG. 4, it is one of the critical features of the present invention that the word line 36 does not overlap the gate oxide layer 35 within the first region 34a of the active region 34.

As shown in FIG. 5, the first deep trench capacitor 32a and 32b are formed inside the substrate 31. The structure of a deep trench capacitor of DRAM cells is known in the art. For the sake of simplicity, the detailed structure of the deep trench capacitors 32a and 32b is not shown in the figures. Briefly, the deep trench capacitor 32a comprises a doped polisilicon layer 46a. Dopants of the doped polisilicon layer 46a diffuse into the adjacent substrate 31 to form a doped region 48a. The doped polisilicon layer 46a and the doped region 48a form a buried strap, which electrically connects a MOS transistor and deep trench capacitor of a DRAM cell. In the test key 30, the buried strap electrically connects the ion well 34c and a polysilicon electrode 46 of the deep trench capacitor 32a. Furthermore, a shallow trench isolation 44 isolates the deep trench capacitor 32a from the deep trench capacitor 32b. The top-thin oxide layer 42a and the shallow trench isolation 44 are simultaneously formed in a single CVD process. Typically, the top-thin oxide layer 42a and the shallow trench isolation 44 are composed of silicon dioxide. The thickness of the top-thin oxide layer 42a is less than the thickness of the shallow trench isolation 44, while greater than the thickness of the gate oxide layer 35.

In the first embodiment of the present invention as set forth in FIG. 4 and FIG. 5, the word line 36 partially passing over the first deep trench capacitor 32a and the second deep trench capacitor 32b. With such layout, the design window of the test key 30 is broadened since the line width of the word line 36 of this invention is greater the line width of the prior art test key. The width of the word line 36 can be adjusted to prevent the word line 36 from being located on the gate oxide layers 35. The breakdown voltage of the top-thin oxide layer 42a is obtained by applying voltages on the word line 36 and the ion wells 34c adjacent to the first deep trench capacitor 32a and second deep trench capacitor 32b. Accordingly, electrical isolation between the word line and the deep trench capacitor can be accurately detected from the test key 30.

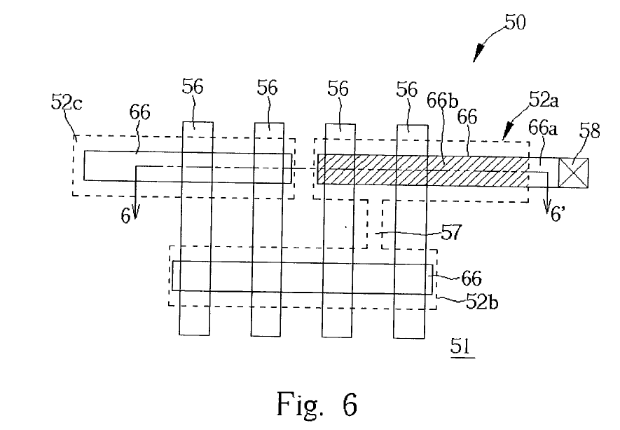

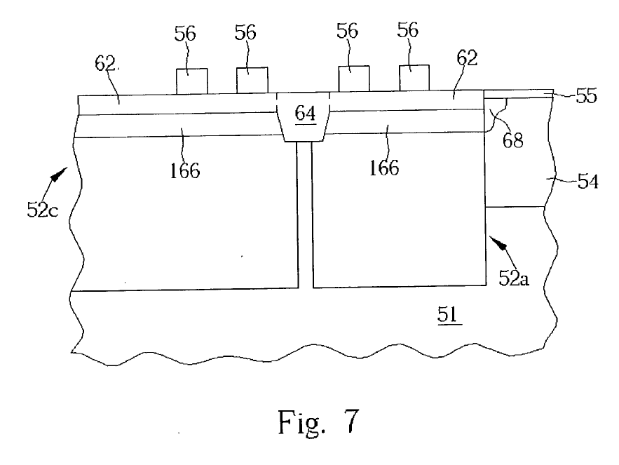

Please refer to FIG. 6 and FIG. 7. FIG. 6 is a schematic diagram of a test key 50 according to the second preferred embodiment of the present invention. FIG. 7 is a cross-sectional view along line 6-6″ of the test key 50 shown in FIG. 6. As shown in FIG. 6, a test key 50 comprises a first deep trench capacitor 52a, a second deep trench capacitor 52b, a dummy deep trench capacitor 52c, a plurality of word lines 56, and a connecting region 57. Outside the active regions 66 is defined as a STI region formed by conventional STI processes. The active regions 66 can be further divided into a first region 66a and a second region 66b. The second region 66b is defined as the overlapping area between the active region 66 and the deep trench capacitors 52a and 52b as indicated by slant lines. The first region 66a includes a thermal gate oxide layer 55 formed over the substrate 51, and the second region 66b includes a top-thin oxide layer 62 filled in a recess of the substrate 51. The formation of the gate oxide layer 55 is known in the art. For example, a high-quality gate oxide layer 55 may be formed by using thermal oxidation process. The top-thin oxide layer 62 is formed by using CVD process. As seen in FIG. 7, each of the active regions 66 further comprises an ion well 54 implanted in an area abutting upon the deep trench capacitor in the substrate 51. A contact 58 is provided and is electrically connected with the ion well 54. The contact 58 is electrically connected with a bit line (not shown) for supplying the ion well 54 with a pre-selected voltage. It should be noted that not every active region 66 of the test key 50 is provided with a contact 58. With reference to FIG. 6, the active region 66 that overlaps with dummy deep trench capacitor 52c is not provided with a contact 58. It should be noted that the word line 56 does not overlap the gate oxide layer 55 within the first region 66a of the active region 66.

The connecting region 57 has similar deep trench capacitor structure as the structure of the deep trench capacitors 52a and 52b in the substrate 51. The deep trench capacitors 52a and 52b, dummy deep trench capacitor 52c, and the connecting region 57 are fabricated in same deep trench capacitor fabrication processes. Through the connecting region 57, the polysilicon electrodes of the deep trench capacitors 52aand 52b are electrically connected with each other. Hence, the voltage supplied by a bit line can be applied to the deep trench capacitors 52a and 52b through one contact 58. The connecting region 57 does not overlap with the word line 56. In other embodiments, the number of the connecting region 57 may be more than one so as to connect two or more deep trench capacitors.

As shown in FIG. 7, the first deep trench capacitor 52a is formed in the substrate 51. The structure of a deep trench capacitor of DRAM cells is known in the art. For the sake of simplicity, the detailed structure of the deep trench capacitors 52a and 52b is not shown in the figures. Briefly, the deep trench capacitor 52a comprises a doped polisilicon layer 166. Dopants of the doped polisilicon layer 166 diffuse into the adjacent substrate 51 to form a doped region 68. The doped polisilicon layer 166 and the doped region 68 form a buried strap, which electrically connects a MOS transistor and deep trench capacitor of a DRAM cell. In the test key 50, the buried strap electrically connects the ion well 54 and a polysilicon electrode of the deep trench capacitor 52a. A shallow trench isolation 64 isolates the deep trench capacitor 52a from the deep trench capacitor 52b. The top-thin oxide layer 62 and the shallow trench isolation 64 are simultaneously formed in a single CVD process. Typically, the top-thin oxide layer 62 and the shallow trench isolation 64 are composed of silicon dioxide. The thickness of the top-thin oxide layer 62 is less than the thickness of the shallow trench isolation 64, while greater than the thickness of the gate oxide layer 55.

In the second preferred embodiment of the present invention as set forth in FIG. 6 and FIG. 7, the area of the top-thin oxide layer 62 on the deep trench capacitor 52a and 52b is increased so that more than one word line 56 are located on the top-thin oxide layer 62 and the shallow trench isolation 64. When measuring the breakdown voltage of the top-thin oxide layer 62, voltages are applied on the word lines 56 and the ion well 54 adjacent to the first deep trench capacitor 52a. As a result, electrical isolation between the word lines 56 and the deep trench capacitors can be accurately detected from the test key 50.

Those skilled in the art will readily observe that numerous modifications and alterations of the device may be made while retaining the teachings of the invention. Accordingly, the above disclosure should be construed as limited only by the metes and bound of the appended claims.

what is claimed is:

1. A test circuit comprising:
a substrate;
a first deep trench polysilicon layer formed in the substrate;
a first top-thin oxide layer disposed over the first deep trench polysilicon layer;
a second deep trench polysilicon layer laterally formed in the substrate on one side of the first deep trench polysilicon layer;
a second top-thin oxide layer disposed over the second deep trench polysilicon layer;
a shallow trench isolation embedded in the substrate and located between the first deep trench polysilicon layer and the second deep trench polysilicon layer; and
a word line laid on the substrate, the word line partially covering the first top-thin oxide layer, the shallow trench isolation, and the second top-thin oxide layer;
an ion well implanted in the substrate and being electrically connected with the first deep trench polysilicon layer; and
a contact electrically connecting the ion well and a bit line for supplying the first deep trench polysilicon layer with a pre-selected voltage.

2. The test circuit of claim 1 wherein the first deep trench polysilicon layer is located at one side of the word line and the second deep trench polysilicon layer is located at the other side of the word line.

3. The test circuit of claim 1 wherein both of thickness of the first top-thin oxide layer and thickness of the second top-thin oxide layer are smaller than a thickness of the shallow trench isolation.

4. The test circuit of claim 1 wherein the shallow trench isolation is formed by performing a shallow trench isolation (STI) process.

5. The test circuit of claim 1 wherein the first top-thin oxide layer, the second top-thin oxide layer, and the shallow trench isolationr are composed of silicon dioxide.

6. The test circuit of claim 5 wherein the first top-thin oxide layer, the second top-thin oxide layer, and the shallow trench isolationr are composed of CVD silicon dioxide.

7. The test circuit of claim 1 wherein the ion well does not overlap with any word line.

8. The test circuit of claim 1 wherein the word line is composed of polysilicon.

9. A test key for evaluating isolation quality of a top-thin oxide layer of deep trench DRAM cells, comprising:
a substrate;
a first deep trench capacitor formed in the substrate;
a first top-thin oxide layer disposed over the first deep trench capacitor;
a second deep trench capacitor formed in the substrate and being electrically connected with the first deep trench capacitor;
a second top-thin oxide layer disposed over the second deep trench capacitor;
a shallow trench isolation embedded in the substrate for isolating the first deep trench capacitor from the second deep trench capacitor;
a first word line formed on the substrate partially covering the first top-thin oxide layer, the shallow trench isolation, and the second top-thin oxide layer,
an ion well implanted in the substrate and being electrically connected with the first deep trench capacitor; and
a contact electrically connecting the ion well and a bit line for supplying the first deep trench capacitor with a pre-selected voltage;
wherein the second deep trench capacitor is electrically connected with the first deep trench capacitor through a connecting region.

10. The test key of claim 9 wherein the connecting region comprises a third deep trench capacitor and the shallow trench isolation covers the third deep trench capacitor.

11. The test key of claim 9 wherein the first deep trench capacitor comprises a polysilicon layer located underneath the first top-thin oxide layer.

12. The test key of claim 11 wherein the polysilicon layer is electrically connected with the ion well through a diffusion region.

13. The test key of claim 9 further comprising a second word line laid on the substrate on at side of the first word line and the second word line partially covers the first top-thin oxide layer, the shallow trench isolation, and the second top-thin oxide layer.

14. The test key of claim 13 wherein the first and second word lines are composed of polysilicon.

15. A test key comprising:
a substrate;
a deep trench capacitor formed in the substrate;
at least one active region defined on the substrate, wherein the active region comprises a first region, a second region and an ion well;
a thermal oxide layer formed in the first region;
a top-thin oxide layer formed in the second region, wherein the second region overlaps with the deep trench capacitor; and
at least one word line partially overlapping with the top-thin oxide layer;
wherein the ion well is electrically connected with a polysilicon electrode of the deep trench capacitor and the thermal oxide layer within the first region does not overlap with any word line.
